(19) United States
(12) Patent Application Publication
(10) Pub. No.: US 2009/0115005 A1
(43) Pub. Date: May 7, 2009

(54) Semiconductor IC and manufacturing method of the same

(76) Inventor: Makoto Watanabe, Sayama-shi (JP)

Correspondence Address: JACOBSON HOLMAN PLLC, 400 SEVENTH STREET N.W., SUITE 600, WASHINGTON, DC, 20004, US

(21) Appl. No.: 11/905,172

(22) Filed: Sep. 27, 2007

(30) Foreign Application Priority Data
Sep. 28, 2006 (JP) P. 2006-264254
Aug. 21, 2007 (JP) P. 2007-214638

(51) Int. Cl. H01L 29/84; H01L 21/50

(52) U.S. Cl. 257/415; 438/51; 257/E29.324; 257/E21.499; 310/348

(57) ABSTRACT

There are disclosed a semiconductor IC whose constitution can be miniaturized to facilitate manufacturing and improve a production efficiency, and a manufacturing method of the semiconductor IC. The manufacturing method of the semiconductor IC includes: forming a wiring line and a circuit element at a front surface of a silicon substrate; forming a concave portion to store a vibration element in a back surface of the silicon substrate by reactive ion etching; forming through holes which pass through the front surface of the silicon substrate and the concave portion in the back surface of the silicon substrate; forming electrode pads on the through holes on the side of the concave portion; storing the vibration element in the concave portion to connect the electrode pads to the vibration element by bump adhesion or adhesion using a conductive adhesive; and sealing the vibration element with a cover.

### BACKGROUND OF THE INVENTION

1. Field of the Invention

The present invention relates to a semiconductor IC and a manufacturing method of the same. More particularly, it relates to a semiconductor IC which can easily be manufactured and which can be miniaturized, and a manufacturing method of the semiconductor IC.

2. Description of the Related Art

A constitution of a conventional module having a crystal element and a semiconductor IC will be described with reference to FIG. 8. FIG. 8 is a sectional explanatory view of the conventional module having the crystal element and the semiconductor IC. It is to be noted that as the conventional module having the crystal element and the semiconductor IC, there is a piezoelectric oscillator for surface mounting.

As shown in FIG. 8, in the conventional module having the crystal element and the semiconductor IC, a stepped portion is disposed in a concave container main body 5 made of laminated ceramic or the like, an end portion of a crystal vibration element 3 is secured to a crystal terminal 6 on the stepped portion with a conductive adhesive 7, a semiconductor integrated circuit (IC) chip 21 is disposed on an inner bottom surface of the container main body 5 in a concave portion, a terminal of the semiconductor IC chip 21 is connected to the container main body 5, and an upper portion of the container main body 5 is provided with a cover 4.

It is to be noted that examples of a similar prior art include Japanese Patent Application Laid-Open No. 2004-173050 (Patent Document 1) and Japanese Patent No. 3634676 (Patent Document 2).

Moreover, examples of a concerned prior art include Japanese Patent Application Laid-Open Nos. 11-103233 (Patent Document 3), 2004-221792 (Patent Document 4) and 2000-244244 (Patent Document 5).

In Patent Document 3, a piezoelectric vibrator is disclosed in which a vibration element is mounted on a lower case including a solid forming substrate and in which an IC is mounted on a lower surface of the lower case.

In Patent Document 4, a piezoelectric oscillator is disclosed in which a crystal vibrator is arranged in an upper concave portion of a package main body and in which IC components are arranged in a lower concave portion of an annular container main body on the back surface of the package main body.

In Patent Document 5, a piezoelectric oscillator is disclosed in which an IC is arranged in a container concave portion of the back surface of a base and in which an opening-concave-portion-like package to contain a crystal vibration plate is arranged on the base back surface.

However, in the conventional module having the crystal element and the semiconductor IC, the IC components and the vibration element are arranged in a concave shape formed at the container main body or the package, but this structure is complicated. Therefore, according to such a constitution, there is a restriction on miniaturization, and a problem has occurred that manufacturing steps cannot be simplified to improve a production efficiency.

### SUMMARY OF THE INVENTION

The present invention has been developed in view of the above situation, and an object thereof is to provide an semiconductor IC whose constitution is miniaturized to facilitate manufacturing thereof, so that a production efficiency can be improved, and a manufacturing method of the semiconductor IC.

The present invention has been developed in view of the above situation, and an object thereof is to provide a frequency selection type oscillator circuit which can output two frequencies without disturbing the miniaturization of a device and which obtains a satisfactory output voltage characteristic.

To solve the above-mentioned problems of the conventional examples, according to the present invention, there is provided a semiconductor IC having a wiring line and a circuit element formed on a front surface of a silicon substrate and having a vibration element which vibrates by piezoelectricity, wherein a concave portion to store the vibration element is formed in a back surface of the silicon substrate, through holes are formed so as to pass through the side of the front surface of the silicon substrate and the concave portion, the through holes on the side of the concave portion are provided with electrodes, and the vibration element stored in the concave portion is connected to the electrodes, so that the circuit can be miniaturized.

Moreover, according to the present invention, there is provided a manufacturing method of a semiconductor IC, comprising: forming a wiring line and a circuit element at a front surface of a silicon substrate; forming a concave portion to store a vibration element in a back surface of the silicon substrate; forming through holes which pass through the front surface of the silicon substrate and the concave portion in the back surface of the silicon substrate; forming electrodes on the through holes on the side of the concave portion; storing the vibration element in the concave portion to connect the electrodes to the vibration element; and sealing the vibration element with a cover. The circuit can be miniaturized, manufacturing steps can be simplified, the circuit can easily be processed on a wafer, and hence the production efficiency can be improved.

Furthermore, according to the present invention, there are provided the semiconductor IC in which the concave portion is formed by reactive ion etching and a manufacturing method of the semiconductor IC, and the concave portion can easily be formed.

In addition, according to the present invention, there are provided the semiconductor IC in which the electrodes formed on the through holes on the side of the concave portion are connected to the vibration element by thermal press using metallic particles or adhesion using a conductive adhesive, so that the vibration element can easily be connected to the electrodes.

### BRIEF DESCRIPTION OF THE DRAWINGS

FIG. 1 shows that a circuit element is prepared and a wiring line pattern is formed at a front surface of an IC, FIG. 1A is a sectional explanatory view, and FIG. 1B is a perspective view;

FIG. 2 shows that a dug concave portion is prepared in a back surface of the IC, FIG. 2A is a sectional explanatory view, and FIG. 2B is a perspective view;

FIG. 3 shows that through holes from the front surface of the IC are prepared, FIG. 3A is a sectional explanatory view, and FIG. 3B is a perspective view;

FIG. 4 shows that electrode pads for a vibration element are prepared at exposed portions of the through holes in the back surface of the IC, FIG. 4A is a sectional perspective view, and FIG. 4B is a perspective view;

FIG. 5 shows that a vibration element is bonded to the electrode pads, FIG. 5A is a sectional explanatory view, and FIG. 5B is a perspective view;

FIG. 6 shows that sealing with a cover is performed, FIG. 6A is a sectional explanatory view, and FIG. 6B is a perspective view;

FIG. 7 shows that the sealing is completed, FIG. 7A is a sectional explanatory view, and FIG. 7B is a perspective view; and

FIG. 8 is a sectional explanatory view of a conventional module having a crystal element and a semiconductor IC.

### DESCRIPTION OF REFERENCE NUMERALS

1 . . . a silicon substrate, 2 . . . electrode pads for a vibration element, 3 . . . the vibration element, 4 . . . a cover, 5 . . . a container main body, 6 . . . a crystal terminal, 7 . . . a conductive adhesive, 10 . . . a circuit element and the like, 11 . . . through holes, 20 . . . bumps and 21 . . . a semiconductor IC chip.

### DESCRIPTION OF THE PREFERRED EMBODIMENT

An embodiment of the present invention will be described with reference to the drawings.

In the present invention, a semiconductor IC has a constitution in which a concave portion to store a vibration element is formed in a back surface of a silicon substrate, and a circuit element and the like at a front surface of the silicon substrate are connected to electrodes of the stored vibration element via through holes formed at the concave portion, so that the circuit can be miniaturized.

Moreover, according to the present invention, in a manufacturing method of a semiconductor IC, a circuit element and a wiring line pattern are formed at a front surface of a silicon substrate, a concave portion to store a vibration element is formed by etching a back surface of the silicon substrate, through holes are formed from the front surface of the silicon substrate toward the concave portion, electrodes are formed on the through holes on the side of the concave portion to bond the vibration element, and the vibration element is sealed with a cover. Since the circuit can be miniaturized and manufacturing steps can be facilitated to process the semiconductor IC in a wafer state, a production efficiency can be improved.

In a semiconductor IC (the present semiconductor IC) according to an embodiment of the present invention, a circuit element and a wiring line pattern are formed at a front surface of a silicon substrate, a concave portion is formed in a back upper surface of the silicon substrate, the concave portion is provided with contact holes to be connected to the circuit element or the wiring line pattern at the front surface, a vibration element is arranged at the concave portion, electrode pads formed on the contact holes of the concave portion are bonded to the vibration element, and an upper portion of the back surface of the silicon substrate is sealed with a cover. Since the fine vibration element is stored in the concave portion formed in the back surface of the silicon substrate, and connected to the circuit element and the like at the front surface via the contact holes, the circuit can effectively be miniaturized.

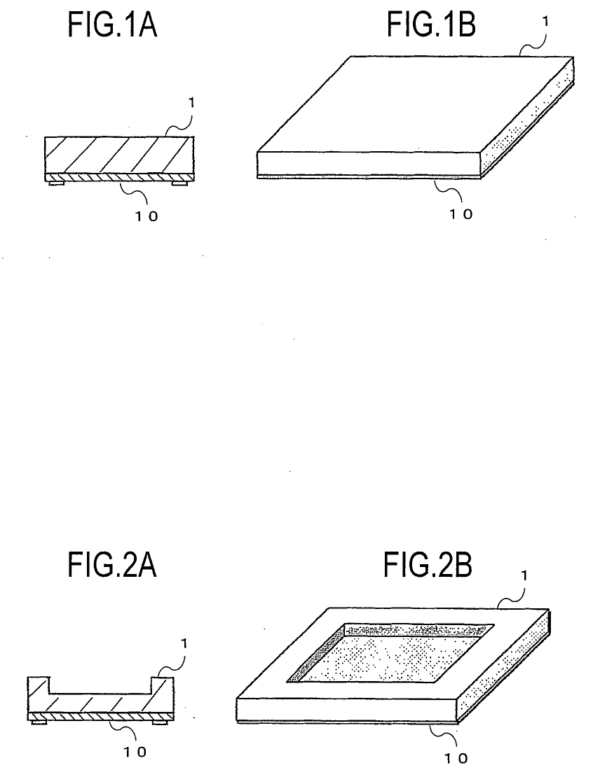

Next, a manufacturing method of a semiconductor IC (the present semiconductor IC) according to the embodiment of the present invention will be described with reference to FIGS. 1 to 7.

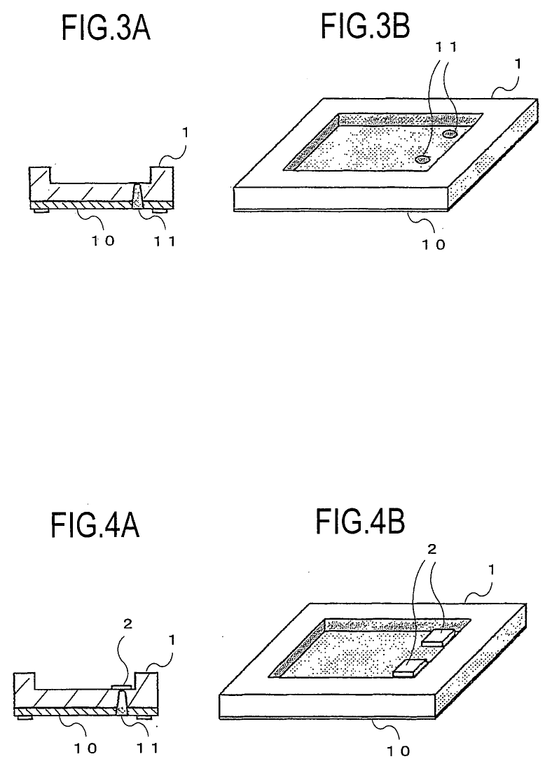

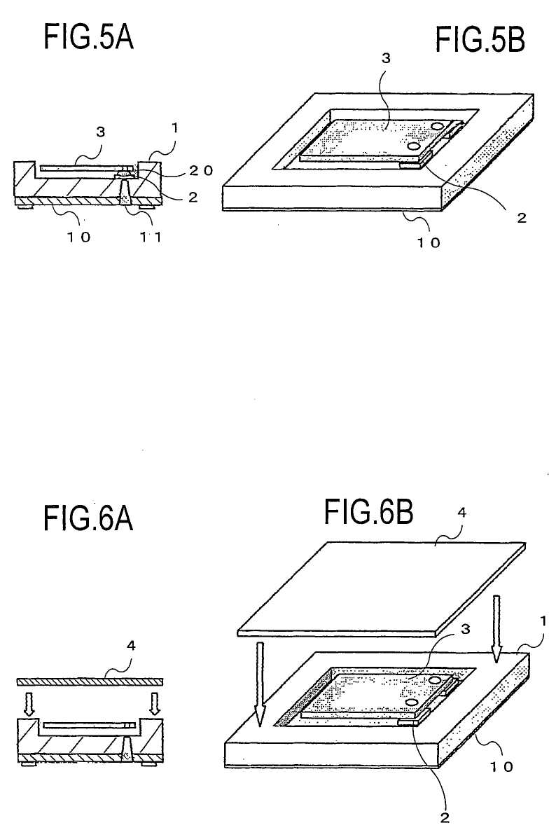

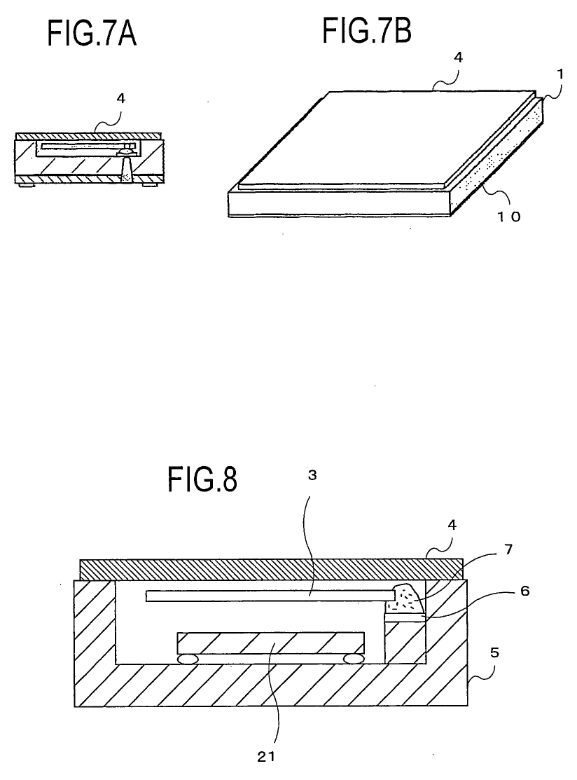

FIG. 1 shows preparation of a circuit element and wiring line patterning at a front surface of an IC, FIG. 1A is a sectional explanatory view, and FIG. 1B is a perspective view; FIG. 2 shows that a dug concave portion is prepared in a back surface of the IC, FIG. 2A is a sectional explanatory view, and FIG. 2B is a perspective view; FIG. 3 shows that through holes from the front surface of the IC are prepared, FIG. 3A is a sectional explanatory view, and FIG. 3B is a perspective view; FIG. 4 shows that electrode pads for a vibration element are prepared in exposed portions of the through holes at the back surface of the IC, FIG. 4A is a sectional perspective view, and FIG. 4B is a perspective view; FIG. 5 shows that a vibration element is bonded to the electrode pads, FIG. 5A is a sectional explanatory view, and FIG. 5B is a perspective view; FIG. 6 shows that sealing with a cover is performed, FIG. 6A is a sectional explanatory view, and FIG. 6B is a perspective view; and FIG. 7 shows that the sealing is completed, FIG. 7A is a sectional explanatory view, and FIG. 7B is a perspective view.

As shown in FIGS. 1A and 1B, in a manufacturing method of the present semiconductor IC, a circuit element, a circuit pattern and an external electrode 10 (hereinafter referred to simply as “the circuit element and the like 10” are prepared at a front surface of a silicon substrate 1 by patterning or the like.

Specifically, the silicon substrate 1 is constituted by integrating, on the front surface thereof, semiconductor elements such as a bipolar transistor and a field-effect transistor, and elements for resistance, capacity and the like. Then, the respective elements are connected via an aluminum wiring line, and the silicon substrate 1 is further provided with circuit terminals for a power source, an output, an earth and the like which become fetch electrodes for the IC.

It is to be noted that as the circuit element of the silicon substrate 1, there is a circuit which requires a crystal vibration element such as a central processing unit (CPU), a radio module IC or a phase locked loop (PLL) IC.

Next, as shown in FIGS. 2A, 2B, reactive ion etching (RIE) is performed on a back surface of the silicon substrate 1 to form a space (a concave portion) for arranging the vibration element in the back surface of the silicon substrate 1.

Next, as shown in FIG. 3A, 3B, two through holes (contact holes) 11 are formed from the front surface of the silicon substrate 1 to the concave portion, for example, by etching and laser processing to prepare electrode pads 2 for the vibration element on exposed portions of the through holes at the back surface of the silicon substrate 1 as shown in FIGS. 4A, 4B.

The through holes 11 are formed, for example, by the following method.

From the front surface of the silicon substrate 1, deep recesses are made by etching or laser processing, and oxidized to form an insulating film on hole walls. Afterward, a low-resistance substance which becomes a conductor, for example, low-resistance polycrystalline silicon is buried in the recesses. Then, the back surface having the concave portion is polished to expose polycrystalline silicon which is the conductor. Next, an aluminum film is disposed on an exposed surface of polycrystalline silicon to form the electrode pads 2 for the vibration element on the side of the concave portion.

It is to be noted that the electrode pads formed at the back surface concave portion are insulated from the silicon substrate by an oxide film in the same manner as in the hole walls.

Next, as shown in FIGS. 5A, 5B, metallic particles (bumps) 20 are formed on the electrode pads 2 for the vibration element in the concave portion, and extraction electrodes (not shown) disposed on a vibration element 3 are bonded to the electrode pads 2 for the vibration element by thermal press using the bumps 20 (bump adhesion) so as to store the vibration element 3 in the concave portion at the back surface of the silicon substrate 1, whereby the vibration element 3 is arranged.

It is to be noted that instead of the bump adhesion, a conductive adhesive may be used as a bonding agent.

Furthermore, as shown in FIGS. 6A, 6B, a cover 4 of silicon or Pyrex (registered trademark) glass is arranged from an upper portion of the vibration element 3, the cover 4 is fixed via the adhesive applied to the back surface of the silicon substrate 1 which comes in contact with the cover 4, or the cover 4 is fixed by anode bonding, and sealing is completed as shown in FIGS. 7A, 7B.

According to the manufacturing method of the present semiconductor IC, since at least the steps of FIGS. 1 to 5 can be performed on a wafer before separated as an individual IC, effects are produced that the manufacturing steps are simplified, homogeneous circuits can be produced in large quantities and a production efficiency can be improved.

It is to be noted that the vibration element 3 is an AT cut piezoelectric vibration element, but the present invention is not limited to this piece, and a tuning fork type piezoelectric vibration element may be used.

Moreover, the present semiconductor IC may be applied to a gyro sensor or the like stored in a package together with an IC chip which oscillates the vibration element.

The present invention is suitable for a semiconductor IC whose constitution is miniaturized to facilitate manufacturing and improve the production efficiency, and a manufacturing method of the semiconductor IC.

1. A semiconductor IC having a wiring line and a circuit element formed on a front surface of a silicon substrate and having a vibration element which vibrates by piezoelectricity,
wherein a concave portion to store the vibration element is formed in a back surface of the silicon substrate, through holes are formed so as to pass through the side of the front surface of the silicon substrate and the concave portion, the through holes on the side of the concave portion are provided with electrodes, and the vibration element stored in the concave portion is connected to the electrodes.

2. The semiconductor IC according to claim 1, wherein the concave portion is formed by reactive ion etching.

3. The semiconductor IC according to claim 1, wherein the electrodes formed on the through holes on the side of the concave portion are connected to the vibration element by thermal press using metallic particles or adhesion using a conductive adhesive.

4. The semiconductor IC according to claim 2, wherein the electrodes formed on the through holes on the side of the concave portion are connected to the vibration element by thermal press using metallic particles or adhesion using a conductive adhesive.

5. The semiconductor IC according to claim 1, wherein the circuit element is a CPU, a radio module IC, or a PLL IC.

6. The semiconductor IC according to claim 2, wherein the circuit element is a CPU, a radio module IC, or a PLL IC.

7. The semiconductor IC according to claim 3, wherein the circuit element is a CPU, a radio module IC, or a PLL IC.

8. The semiconductor IC according to claim 4, wherein the circuit element is a CPU, a radio module IC, or a PLL IC.

9. A manufacturing method of a semiconductor IC, comprising:
forming a wiring line and a circuit element at a front surface of a silicon substrate;
forming a concave portion to store a vibration element in a back surface of the silicon substrate;
forming through holes which pass through the front surface of the silicon substrate and the concave portion in the back surface of the silicon substrate;
forming electrodes on the through holes on the side of the concave portion;
storing the vibration element in the concave portion to connect the electrodes to the vibration element; and
sealing the vibration element with a cover.

10. The manufacturing method of the semiconductor IC according to claim 9, wherein the concave portion is formed by reactive ion etching.

11. The manufacturing method of the semiconductor IC according to claim 9, wherein the electrodes formed on the through holes on the side of the concave portion are connected to the vibration element by thermal press using metallic particles or adhesion using a conductive adhesive.

12. The manufacturing method of the semiconductor IC according to claim 10, wherein the electrodes formed on the through holes on the side of the concave portion are connected to the vibration element by thermal press using metallic particles or adhesion using a conductive adhesive.
